(19) United States
(12) Patent Application Publication
(10) Pub. No.: US 2026/0204517 A1
(43) Pub. Date: Jul. 16, 2026

(54) PLASMA PROCESSING SYSTEMS WITH DIRECT CURRENT VOLTAGE FOR PLASMA ENERGY CONTROL

(71) Applicant: Applied Materials, Inc., Santa Clara, CA (US)

(72) Inventors: Shinjae HWANG, Santa Clara, CA (US); Chengyu WEN, Santa Clara, CA (US); Kishor KALATHIPARAMBIL, Santa Clara, CA (US); Prashanth KOTHNUR, San Jose, CA (US)

(21) Appl. No.: 19/024,233

(22) Filed: Jan. 16, 2025

(51) Int. Cl. H01J 37/32

(52) U.S. Cl. CPC H01J 37/32174; H01J 37/32128; H01J 37/32568; H01J 37/32715; H01J 2237/3321; H01J 2237/3341

(57) ABSTRACT

Methods and apparatus for processing a substrate using a plasma processing system. One example plasma processing system generally includes a first electrode, a second electrode, and a system controller comprising one or more processors and memory that includes computer-executable instructions. The one or more processors are generally configured to execute the computer-executable instructions and cause the plasma processing system to: deliver, using a first radio frequency (RF) generator, a first RF waveform to the first electrode at a first RF frequency, and adjust, using a direct current (DC) supply, a voltage applied to the second electrode during the delivery of the first RF waveform.

### BACKGROUND

### Filed

Embodiments described herein generally relate to a system and methods used in semiconductor device fabrication. More specifically, embodiments of the present disclosure relate to a plasma processing system used to process a substrate.

### DESCRIPTION OF THE RELATED ART

Reliably producing high aspect ratio features is one of the key technology challenges for the next generation of semiconductor devices. One method of forming high aspect ratio features uses a plasma-assisted etching process to bombard a material formed on a surface of a substrate through openings formed in a patterned mask layer formed on the substrate surface.

With technology node advancing towards 2 nanometers (nms), the fabrication of smaller features with larger aspect ratios requires atomic precision for plasma processing. For etching processes where the plasma ions play a major role, ion energy control is always challenging the semiconductor equipment industry. In a typical plasma-assisted etching process, the substrate is positioned on an electrostatic chuck (ESC) disposed in a processing chamber, a plasma is formed over the substrate, and ions are accelerated from the plasma towards the substrate across a plasma sheath, i.e., a region depleted of electrons, formed between the plasma and the surface of the substrate. Additionally, RF substrate biasing methods, which require the use of a separate RF biasing source in addition to the RF generator that is used to initiate and maintain the plasma in the plasma processing chamber, have been unable to desirably control the plasma sheath properties to achieve desirable plasma processing results that will allow the formation of these smaller device feature sizes. The traditional RF generator and RF biasing methods utilize sinusoidal RF waveforms to excite the plasma and form the plasma sheath often leads to undesirable and inconsistent process results due to sinusoidal shape of the RF waveform and the inability of the RF biasing methods to adjust the ion energy during processing due to limitations in the provided sinusoidal waveform characteristics.

Accordingly, there is a need in the art for improved plasma processing systems and methods that solve the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments provided herein generally include apparatus, plasma processing systems, and methods for plasma processing of a substrate in a plasma processing chamber.

Embodiments of the present disclosure provide a plasma processing system. The plasma processing system generally includes a first electrode, a second electrode, and a system controller comprising one or more processors and memory that includes computer-executable instructions. The one or more processors are generally configured to execute the computer-executable instructions and cause the plasma processing system to: deliver, using a first radio frequency (RF) generator, a first RF waveform to the first electrode at a first RF frequency, and adjust, using a direct current (DC) supply, a voltage applied to the second electrode during the delivery of the first RF waveform.

Embodiments of the present disclosure are directed to a method. The method generally includes (i) delivering, using a first radio frequency (RF) generator, a first RF waveform to a first electrode at a first RF frequency to form a plasma in a processing volume within a plasma processing system, and (ii) adjusting, using a direct current (DC) supply, a voltage applied to a second electrode while the plasma is formed in the processing volume by the delivery of the first RF waveform, wherein the processing volume is disposed between the second electrode and the first electrode.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example plasma processing system, in accordance with certain embodiments of the present disclosure.

FIG. 1B is a schematic representation of an example plasma processing system with an additional direct current (DC) supply, in accordance with certain embodiments of the present disclosure.

FIG. 2 is a flow diagram illustrating example operations for plasma ion energy control, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for tuning the plasma potential of a plasma formed in a plasma processing system (e.g., to control the ion energy and/or the flux of the plasma) during plasma processing of semiconductor substrates while forming and maintaining a desired ion angular distribution function (IADF). Such a plasma processing system may include a plasma processing chamber that includes a first electrode, a second electrode, and a processing region disposed between the first electrode and the second electrode. The first electrode (e.g., which may be a lower electrode) may be a bias electrode of the plasma processing chamber, and the second electrode (e.g., which may be an upper electrode) may be a faceplate or showerhead of the plasma processing chamber. In some embodiments, the first electrode may be parallel and opposite to the second electrode. While the disclosure provided herein often describes the first electrode as being the lower electrode, or any electrode as being the lower electrode, and the second electrode as being the upper electrode, or any electrode as being the upper electrode, this configuration is not intended to be limiting as to the scope of the disclosure herein since in some cases it may be desirable for the orientation and/or biasing configuration of these electrodes to be flipped (e.g., first electrode being the upper electrode and the second electrode being the lower electrode) or generally aligned in an alternate non-vertically aligned opposing orientation.

The plasma processing system may include (i) one or more radio frequency (RF) generators configured to deliver one or more RF waveforms to the first electrode, and (ii) a direct current (DC) supply configured to apply a voltage to the second electrode during the delivery of the one or more RF waveforms. In this manner, the plasma potential (i.e., voltage) of the plasma may be adjusted (e.g., increased or decreased) using the DC supply while the IADF of ions landing on a semiconductor substrate in the plasma processing system during plasma processing is maintained, thereby improving plasma uniformity control. Additionally, the voltage at the second electrode (e.g., which may be disposed above the plasma) may be separately and individually controlled relative to the voltage at the first electrode (e.g., which may be disposed below the plasma).

### Processing System Examples

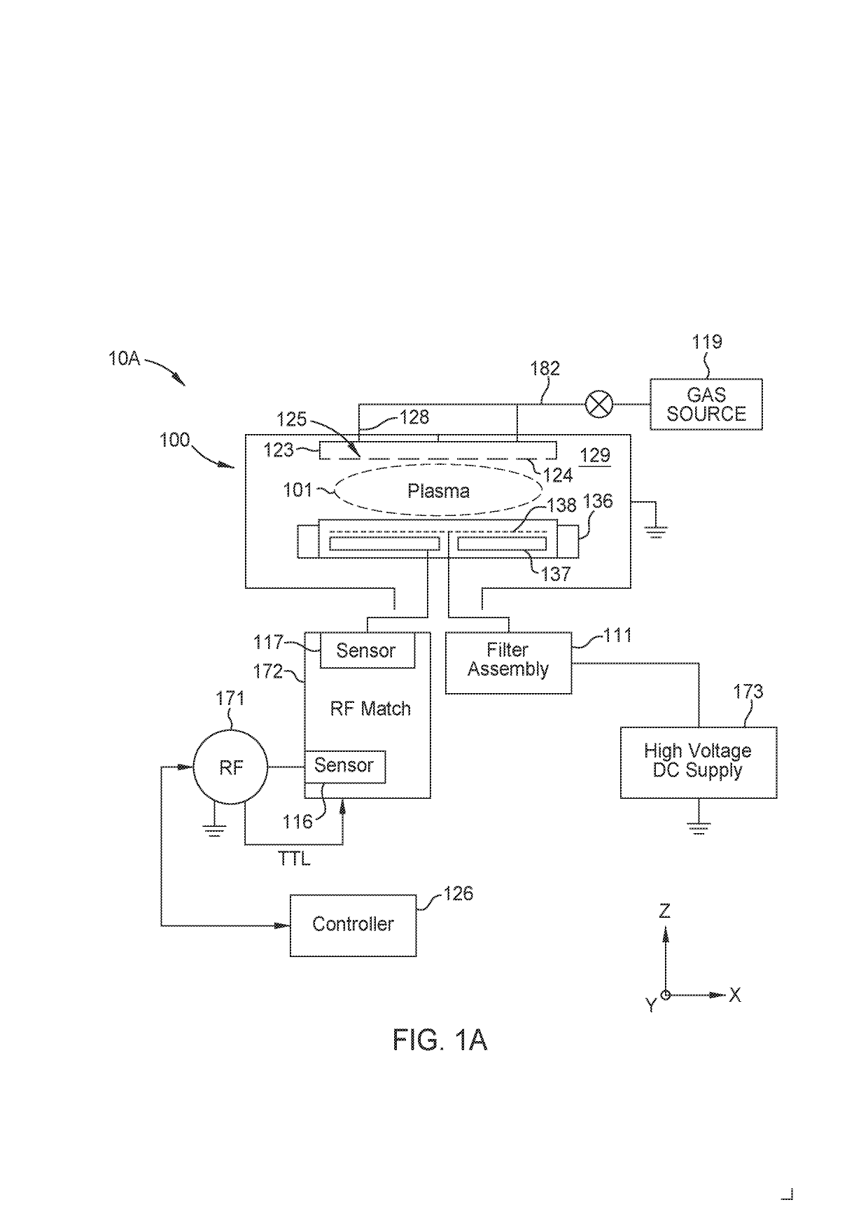

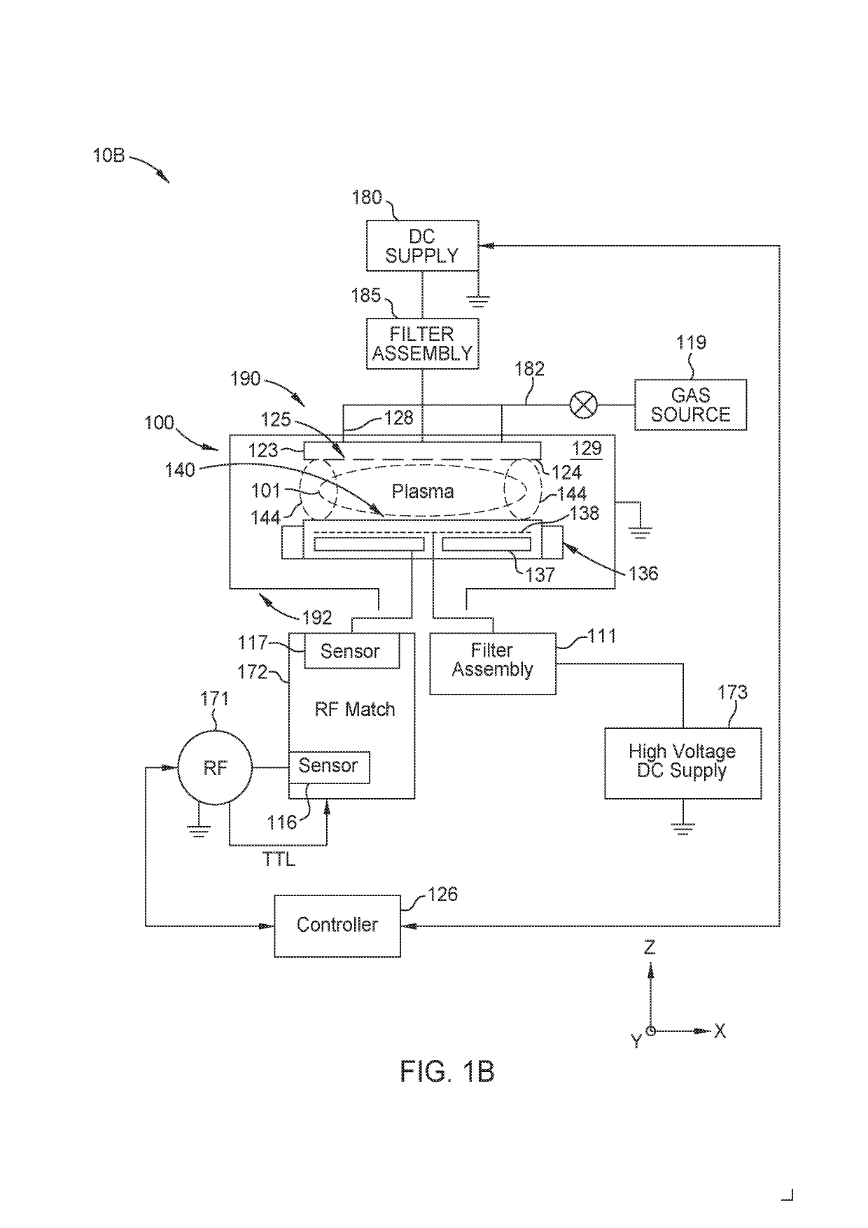

FIG. 1A is a schematic representation of an example plasma processing system 10A, in accordance with certain embodiments of the present disclosure. The plasma processing system 10A is configured for plasma-assisted substrate processing process, such as a plasma-assisted etching process or deposition process. In some examples, a plasma-assisted process include a plasma-assisted etching process, such as a reactive ion etch (RIE) process. The plasma processing system 10A can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In some embodiments, as shown in FIG. 1A, the plasma processing system 10A is configured to form a capacitively-coupled-plasma (CCP). In other embodiments, a plasma may alternately be generated by an inductively coupled plasma (ICP) source disposed over a processing region of the plasma processing system 10A.

The plasma processing system 10A includes a processing chamber 100, a substrate support assembly 136, a gas delivery system 182, a high voltage direct current (DC) supply 173, a RF generator 171, and a RF match 172 (e.g., RF impedance matching networks). The processing chamber 100 includes a chamber lid 123 positioned in the processing volume 129 of the processing chamber 100. The chamber lid 123 includes one or more sidewalls and a chamber base that are configured to withstand the pressures and energy applied to them while a plasma 101 is generated within a vacuum environment maintained in a processing volume 129 of the processing chamber 100 during processing. The chamber lid 123 also includes a faceplate 124 (e.g., a showerhead) with one or more openings 125. Although a plurality of openings 125 are illustrated, it is to be understood that any number of openings 125 may be included.

The gas delivery system 182, which is coupled to the processing volume 129 of the processing chamber 100, is configured to deliver at least one processing gas from at least one gas source 119 to the processing volume 129 of the processing chamber 100. The gas delivery system 182 includes the gas source 119 and one or more gas inlets 128 positioned through the chamber lid 123. The gas inlets 128 may be configured to deliver one or more processing gasses to the processing volume 129 of the processing chamber 100 through the openings 125 of the faceplate 124.

The processing chamber 100 also includes a substrate support assembly 136 positioned in the processing volume 129 of the processing chamber 100. In some embodiments, the chamber lid 123 (and/or the faceplate 124) is coupled to ground and thus acts as an upper electrode during plasma processing. In some embodiments, the RF generator 171 is electrically coupled to a lower electrode, such as the RF baseplate 137 and/or a bias electrode 138. The RF generator 171 is configured to deliver a RF signal to ignite and maintain the plasma 101 between the upper and lower electrode(s). In one example, the RF generator 171 may deliver a RF source power to the RF baseplate 137 and/or the bias electrode 138 within the substrate support assembly 136 (e.g., a cathode assembly) for plasma production. However, in some alternative configurations, the RF generator 171 can be electrically coupled to the upper electrode. A center frequency of the RF source power can be from 13.56 megahertz (MHz) to very high frequency band such as 40 MHz, 60 MHz, 120 MHz or 162 MHz. The RF source power can be operated in a continuous mode or a pulsed mode. A pulsing frequency of the RF source power can be from 10 to 100 kHz, and duty cycles are ranging from 5% to 95%. The RF generator 171 has a frequency tuning capability and can adjust its RF power frequency within e.g., ±5% or ±10%. In some embodiments, the RF generator 171 switches the RF power frequency at a predefined speed (e.g., two nanoseconds, fifty nanoseconds, etc.).

The substrate support assembly 136 is coupled to the RF generator 171, and the RF generator 171 may be configured to deliver a RF signal to the processing volume 129 of the processing chamber 100. The RF generator 171 is electronically coupled to the RF match 172 disposed between the RF generator 171 and the processing volume 129 of the processing chamber 100. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172) are designed to only allow powers in a selected frequency range, and to isolate RF power supplies from each other. In some cases, a bandwidth of a RF filter has to be larger than a frequency tuning range of the RF generator 171.

During the plasma processing, the RF generator 171 delivers a RF signal to the RF baseplate 137 of the substrate support assembly 136 via the RF match 172. For example, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, it may be beneficial to find a match impedance (e.g., a matching point) by adjusting one or more components of the RF match 172 as the source and load impedances change. The RF match 172 is electrically coupled to the RF generator 171 and the substrate support assembly 136. The RF match 172 is configured to receive a synchronization signal from the RF generator 171.

In some embodiments, two or more RF signals may be delivered to the RF baseplate 137 and/or the bias electrode 138 during the plasma processing. In some cases, the RF generator 171 may be configured to deliver the two or more different RF signals, whereas in other cases, a plurality of RF generators 171 may be included in the plasma processing system 10A for delivering a plurality of different RF signals. The additional RF generators 171 may share the RF match 172, or additional RF matches 172 may be included. In some cases, the two or more RF signals may be delivered at different frequencies. For example, one RF signal may be delivered at 13.56 MHz (e.g., using between 50 and 500 watts of power) while another RF signal may be delivered at 60 MHz (e.g., using between 100 and 1200 watts of power). It is to be understood that the embodiments herein may include, for example, using a single RF signal (e.g., single RF power) or dual RF signals (e.g., dual RF power) during plasma processing in the plasma processing system 10A.

The substrate support assembly 136 may be coupled to a high voltage DC supply 173 that supplies a chucking voltage thereto. The high voltage DC supply 173 may be coupled to the bias electrode 138. The high voltage DC supply 173 may be coupled to a filter assembly 111 that is disposed between the high voltage DC supply 173 and the bias electrode 138 disposed within the substrate support assembly 136. The filter assembly 111 is configured to electronically isolate the high voltage DC supply 173 during plasma processing. In one configuration, a static DC voltage is between about -5000V and about +5000V, and is delivered using an electrical conductor (such as a coaxial power delivery line). The filter assembly 111 may include multiple filtering components or a single common filter that are configured to block the RF signals generated during processing from making their way back to the high voltage DC supply 173.

Voltage and current sensors can be placed at an input and/or output of the RF match 172 to measure impedance and other parameters. These sensors can be synchronized using an external transistor-transistor logic (TTL) synchronization signal from an advanced waveform generator and/or RF generators or using measured voltage and current data to determine timing internally. For example, an output sensor 117 is configured to measure the impedance of the processing chamber 100, and other characteristics such as the voltage, current, harmonics, phase, and/or the like. An input sensor 116 is configured to measure the impedance of the RF generator 171 and other characteristics such as the voltage, current, harmonics, phase, and/or the like. Based on either of the synchronization signals or the characteristics of the processing chamber 100, the RF match 172 is able to capture fast impedance changes and optimize impedance matching.

Typically, the bias electrode 138 is formed of one or more electrically conductive parts, such as one or more metal meshes, foils, plates, or combinations thereof. The high voltage DC supply 173 is applied to chuck a wafer during a process for a thermal control.

The RF generator 171 may be directly coupled to a system controller 126. The system controller 126 controls the generated RF signal. The system controller 126, also referred to herein as a processing chamber controller, includes a central processing unit (CPU), a memory, and support circuits. The system controller 126 is used to control the process sequence used to process a substrate disposed on the substrate support assembly 136, including the substrate biasing described herein. The CPU is a general-purpose computer processor configured for use in an industrial setting for controlling the processing chamber and sub-processors related thereto. The memory described herein, which is generally non-volatile memory, may include random access memory, read-only memory, floppy or hard disk drive, or other suitable forms of digital storage, local or remote. The support circuits are conventionally coupled to the CPU and comprise cache, clock circuits, input/output subsystems, power supplies, and the like, and combinations thereof. Software instructions (program) and data can be coded and stored within memory to instruct a processor within CPU. A software program (or computer instructions) readable by CPU in the system controller 126 determines which tasks are performable by the components in the plasma processing system 10A.

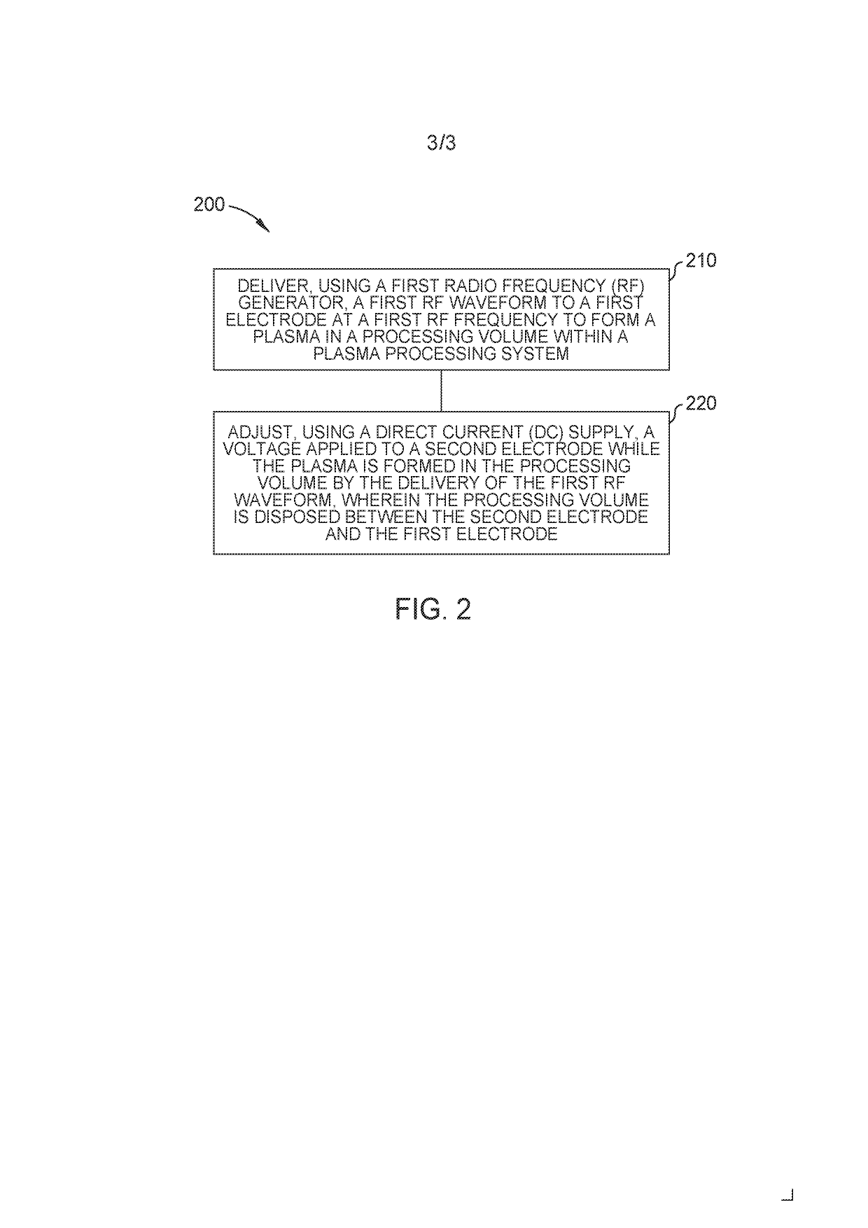

Typically, the program, which is readable by the CPU in the system controller 126, includes code, which, when executed by the CPU, performs tasks relating to the plasma processing schemes described herein. The program may include instructions that are used to control the various hardware and electrical components within the plasma processing system 10A to perform the various process tasks and various process sequences used to implement the methods described herein. In some embodiments, the program includes instructions that are used to perform one or more of the operations described below in relation to FIG. 2.

In some cases, as the ion energy of a plasma formed in a plasma processing system during plasma processing of semiconductor substrates increases, the ion angular distribution function (IADF) may become narrower, because of the increased bias at the semiconductor substrate. However, it is often preferable to be able to increase the ion energy of the plasma while maintaining a wide IADF. Controlling the power of a single or dual frequency radio frequency (RF) waveform (e.g., by controlling one or more RF generators in the plasma processing system) may enable some expansion of the range of ion energy of the plasma formed in the plasma processing system. Nevertheless, it may desirable in certain situations to further expand the range of ion energy of the plasma in a plasma processing system during plasma processing of semiconductor substrates.

Certain embodiments of the present disclosure may utilize a DC voltage applied to an electrode within a processing chamber, such as the upper electrode during plasma processing to provide a greater range of control for the plasma potential (i.e., voltage) of a plasma formed in a plasma processing system (e.g., thereby enabling a greater control over the range of ion energies in the plasma), while still maintaining a desired wide IADF. In this manner, the plasma potential of a plasma formed in the plasma processing system may be increased without compromising the IADF.

FIG. 1B is a schematic representation of an example plasma processing system 10B with an additional DC supply 180 that is coupled to an electrode within the processing chamber 100, in accordance with certain embodiments of the present disclosure. The plasma processing system 10B may be similar to the plasma processing system 10A, but may include the DC supply 180 and optionally a filter assembly 185. The DC supply 180 may be configured to apply a reference voltage to the chamber lid 123. In this manner, the chamber lid 123 may effectively function as the second electrode (e.g., upper electrode) described above. In some embodiments, the chamber lid 123 includes the faceplate 124 that includes the plurality of openings 125 that are configured to receive a gas from the gas source 119. In some cases, the second electrode (e.g., upper electrode) may effectively act as a RF signal return electrode and the first electrode (e.g., lower electrode) may effectively be a RF bias electrode. In some cases, the second electrode (e.g., upper electrode) may be a large area electrode that opposes the first electrode (e.g., the RF baseplate 137 and/or the bias electrode 138). For example, the second electrode may be positioned over the first electrode, and the processing volume 129 may be formed between the first electrode and the second electrode.

In some embodiments, the size of the second electrode may be equal to or within ±20% of the size of the substrate. In these embodiments, the size of the first electrode may be substantially equal to the size of the substrate. For example, the size of the substrate may be 300 millimeters (mm), the size of the second electrode may be about 20% higher than the size of the substrate, and the first electrode may be substantially equal to the size of the substrate. In some embodiments, a plasma facing surface area of the second electrode may equal (or about equal) to a plasma facing surface area of the first electrode. In some cases, the space between the second electrode and the first electrode (e.g., plate-to-plate) may be between 7 mm and 15 mm.

In some embodiments, the chamber lid 123 may be disposed adjacent to a first edge 190 of the processing chamber 100 and the substrate support assembly 136 may be disposed adjacent to a second edge 192 of the processing chamber 100, the second edge 192 being opposite the first edge 190, as illustrated. Said differently, the second edge 192 may be disposed in the positive Z-direction (e.g., in the upper part of the processing chamber 100 and disposed above the processing volume 129) relative to the first edge 190 (e.g., which is in the lower part of the processing chamber 100 and disposed below the processing volume 129). The second electrode may be disposed adjacent to the chamber lid 123, and the first electrode may be disposed adjacent to the substrate support assembly 136. In some cases, the first electrode and the second electrode may be aligned parallel to a surface 140 of the substrate support assembly 136.

The DC voltage applied to the chamber lid 123 (and/or the faceplate 124) may be, for example, between -300 and 300 volts, such as between 150 and 250 volts. In some cases, the voltage applied to the chamber lid 123 (and/or the faceplate 124) may be about 200 volts.

The optional filter assembly 185 may be similar to the filter assembly 111, may be coupled between the upper electrode and the DC supply 180, and may be configured to electronically isolate the DC supply 180 during plasma processing. The filter assembly 185 may include multiple filtering components or a single common filter.

The DC supply 180 (along with the RF generator 171) is in communication with the system controller 126. The system controller 126 controls the voltage applied by the DC supply 180 and the generated RF signal provided by the RF generator 171.

In some embodiments, the DC voltage may be applied (using the DC supply 180) to the chamber lid 123 (and/or the faceplate 124) separately or in combination with (i) the high voltage DC supply 173 applying a DC voltage to the bias electrode 138 and/or applying a DC voltage to the RF baseplate 137, and/or (ii) the RF generator 171 delivering a RF source power to the bias electrode 138 and/or delivering a RF source power to the RF baseplate 137. In this manner, three electrodes (e.g., the chamber lid 123 and/or the faceplate 124, the RF baseplate 137, and the bias electrode 138) may be used jointly for plasma-assisted substrate processing process in the plasma processing system 10B.

In some cases, the RF generator 171 may deliver a RF source power to the RF baseplate 137, the high voltage DC supply 173 may apply a DC voltage to the bias electrode 138, and the DC supply 180 may apply a DC voltage to the chamber lid 123 (and/or the faceplate 124). In other cases, the RF generator 171 may deliver a RF source power to the bias electrode 138, the high voltage DC supply 173 may apply a DC voltage to the bias electrode 138, and the DC supply 180 may apply a DC voltage to the chamber lid 123 (and/or the faceplate 124). In yet other cases, the RF generator 171 may deliver a RF source power to the RF baseplate 137 and deliver a RF source power to the bias electrode 138, the high voltage DC supply 173 may apply a DC voltage to the bias electrode 138, and the DC supply 180 may apply a DC voltage to the chamber lid 123 (and/or the faceplate 124). In yet other cases, the RF generator 171 may deliver a RF source power to the RF baseplate 137 and deliver a RF source power to the bias electrode 138, the high voltage DC supply 173 may apply a DC voltage to the bias electrode 138 and may apply a DC voltage to the RF baseplate 137, and the DC supply 180 may apply a DC voltage to the chamber lid 123 (and/or the faceplate 124). It is to be understood that these cases are merely illustrative, and that any combination of applying the high voltage DC supply 173 to the bias electrode 138 and/or the RF baseplate 137 and delivering a RF source power to the bias electrode 138 and/or delivering a RF source power to the RF baseplate 137 (while the DC voltage is applied to the chamber lid 123 and/or the faceplate 124) may be used.

Embodiments described herein may enable the voltage of the plasma 101 to be adjusted (e.g., increased or decreased, using the DC supply 180) during the delivery of the one or more RF signals while the IADF of ions landing on a semiconductor substrate (e.g., which may be disposed on the surface 140 of the substrate support assembly 136) in the plasma processing system 10B during plasma processing may be maintained, thereby providing improved plasma uniformity control. Additionally, the voltage at the second electrode may be separately and individually controlled relative to the voltage at the first electrode (e.g., to enable greater control in edge regions 144, which are illustrated in FIG. 1B). For example, the voltage at the second electrode (e.g., a plate in a showerhead) may be controlled (e.g., using the DC supply 180) to have a lower voltage than the first electrode (e.g., a bias electrode in a substrate support assembly), such that high ion energy may be obtained at a substrate disposed on the substrate support assembly 136 without sputtering from the faceplate (e.g., implemented as a showerhead).

Furthermore, the plasma processing system 10B described herein may enable, for example, the removal of impurities from metal thin films with organic residue, the densification of films of metal nitrides by removing excess nitrogen, and/or the removal of oxygen/halide impurities in a substrate during plasma processing.

### Operation for Plasma Energy Control

FIG. 2 is a flow diagram illustrating example operations 200 for plasma ion energy control, in accordance with certain embodiments of the present disclosure. The operations 200 may be performed by a plasma processing system, such as the plasma processing system 10B of FIG. 1B. In some cases, the operations 200 may be performed by control circuitry (e.g., system controller 126) included in the plasma processing system.

The operations 200 may include, at block 210, delivering, using a first radio frequency (RF) generator (e.g., RF generator 171), a first RF waveform to a first electrode (e.g., lower electrode, such as the RF baseplate 137 and/or a bias electrode 138) at a first RF frequency (e.g., at least one of 13.56 megahertz (MHz), 40 MHz, 60 MHz, 120 MHz, 162 MHz, etc.) to form a plasma (e.g., plasma 101) in a processing volume (e.g., processing volume 129) within a plasma processing system (e.g., plasma processing system 10B).

At block 220, the operations 200 may include adjusting, using a direct current (DC) supply (e.g., DC supply 180), a voltage applied to a second electrode (e.g., upper electrode, such as chamber lid 123 and/or faceplate 124) while the plasma is formed in the processing volume by the delivery of the first RF waveform. In some embodiments, the processing volume may be disposed between the second electrode and the first electrode. The voltage may be between -300 volts and 300 volts. For example, the voltage may be between 150 volts and 250 volts.

According to certain embodiments, the operations 200 may include applying, using a high voltage supply (e.g., high voltage DC supply 173), a DC voltage to a third electrode (e.g., bias electrode 138) disposed within a substrate support assembly (e.g., substrate support assembly 136). In these cases, the first electrode may also be disposed within the substrate support assembly. For example, and as described above, the operations 200 may include delivering the first RF waveform to the first electrode (implemented as the RF baseplate 137 in the substrate support assembly 136) at block 210, applying a DC voltage to the third electrode (implemented as bias electrode 138 in the substrate support assembly 136), and adjusting the voltage applied to the second electrode (implemented as chamber lid 123 and/or faceplate 124).

According to certain embodiments, the operations 200 may include applying, using the high voltage supply, a DC voltage to the first electrode. In these cases, the first electrode may be disposed within the substrate support assembly. For example, and as described above, the operations 200 may include delivering the first RF waveform to the first electrode (implemented as the bias electrode 138 in the substrate support assembly 136) at block 210, applying a DC voltage to the first electrode, and adjusting the voltage applied to the second electrode (implemented as chamber lid 123 and/or faceplate 124).

According to certain embodiments, the operations 200 may include delivering a second RF waveform to the first electrode at a second RF frequency (e.g., at least one of 13.56 MHz, 40 MHz, 60 MHz, 120 MHz, 162 MHz, etc.). The second RF frequency may be different (e.g., higher or lower) than the first RF frequency. In some cases, the adjusting of the voltage applied to the second electrode may occur during delivery of the second RF waveform (and the first RF waveform). The second RF waveform may be delivered using the first RF generator or another RF generator.

The second electrode may be positioned over the first electrode and the processing volume may be formed between the first electrode and the second electrode. The first electrode and the second electrode may be included in a processing chamber (e.g., processing chamber 100), and a processing volume may be disposed between the first electrode and the second electrode. The processing chamber may further include a chamber lid (e.g., the chamber lid 123) disposed adjacent to a first edge (e.g., first edge 190) of the processing chamber and a substrate support assembly (e.g., substrate support assembly 136) disposed adjacent to a second edge (e.g., second edge 192) of the processing chamber. The second edge may be opposite the first edge, the second electrode may be disposed adjacent to the chamber lid, and the first electrode may be disposed adjacent to the substrate support assembly. In some cases, the first electrode and the second electrode may be aligned parallel to a surface (e.g., surface 140) of the substrate support assembly.

As described above, the first electrode may effectively be a bias electrode, and the second electrode may effectively be a RF return electrode that is coupled to ground.

In some embodiments, a filter assembly (e.g., filter assembly 185) may be coupled between the second electrode and the DC supply.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/-10% variation from the nominal value. It is to be understood that such a variation can be included in any value provided herein.

As used herein, “a processor,” “at least one processor,” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” or “one or more of” a list of items refers to any combination of those items, including single members. As an example, “at least one of: a, b, or c” is intended to cover: a, b, c, a-b, a-c, b-c,and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The term "coupled" is used herein to refer to the direct or indirect coupling between two objects. For example, if object A physically touches object B and object B touches object C, then objects A and C may still be considered coupled to one another - even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

We claim:

1. A plasma processing system comprising:
a first electrode;
a second electrode; and
a system controller comprising memory that includes computer-executable instructions and one or more processors configured to execute the computer-executable instructions and cause the plasma processing system to:
deliver, using a first radio frequency (RF) generator, a first RF waveform to the first electrode at a first RF frequency; and
adjust, using a direct current (DC) supply, a voltage applied to the second electrode during the delivery of the first RF waveform.

2. The plasma processing system of claim 1, further comprising:
a high voltage supply that is configured to apply a DC voltage to a third electrode disposed within a substrate support assembly,
wherein the first electrode is disposed within the substrate support assembly.

3. The plasma processing system of claim 2, wherein the second electrode is positioned over the first electrode and a processing volume is formed between the first electrode and the second electrode.

4. The plasma processing system of claim 1, further comprising:
a high voltage supply that is configured to apply a DC voltage to the first electrode, wherein the first electrode is disposed within a substrate support assembly.

5. The plasma processing system of claim 4, wherein the second electrode is positioned over the first electrode and a processing volume is formed between the first electrode and the second electrode.

6. The plasma processing system of claim 1, wherein the one or more processors are further configured to:
deliver a second RF waveform to the first electrode at a second RF frequency, wherein the second RF frequency is different than the first RF frequency, and wherein the voltage applied to the second electrode is adjusted during the delivery of the second RF waveform.

7. The plasma processing system of claim 1, further comprising a processing chamber that comprises:
a chamber lid disposed adjacent to a first edge of the processing chamber; and
a substrate support assembly disposed adjacent to a second edge of the processing chamber, wherein:
the second edge is opposite the first edge;
the second electrode is disposed adjacent to the chamber lid; and
the first electrode is disposed adjacent to the substrate support assembly.

8. The plasma processing system of claim 7, wherein the first electrode and the second electrode are aligned parallel to a surface of the substrate support assembly.

9. The plasma processing system of claim 7, wherein:
the first electrode is a bias electrode; and
the second electrode is a RF return electrode that is coupled to ground.

10. The plasma processing system of claim 1, further comprising a filter assembly coupled between the second electrode and the DC supply.

11. A method comprising:
delivering, using a first radio frequency (RF) generator, a first RF waveform to a first electrode at a first RF frequency to form a plasma in a processing volume within a plasma processing system; and
adjusting, using a direct current (DC) supply, a voltage applied to a second electrode while the plasma is formed in the processing volume by the delivery of the first RF waveform, wherein the processing volume is disposed between the second electrode and the first electrode.

12. The method of claim 11, further comprising:
applying, using a high voltage supply, a DC voltage to a third electrode disposed within a substrate support assembly,
wherein the first electrode is disposed within the substrate support assembly.

13. The method of claim 11, further comprising:
delivering a second RF waveform to the first electrode at a second RF frequency, wherein the second RF is different than the first RF frequency, and wherein the voltage applied to the second electrode is adjusted during the delivery of the second RF waveform.

14. The method of claim 11, wherein the second electrode is positioned over the first electrode and the processing volume is formed between the first electrode and the second electrode.

15. The method of claim 14, further comprising a processing chamber that comprises:
a chamber lid disposed adjacent to a first edge of the processing chamber; and
a substrate support assembly disposed adjacent to a second edge of the processing chamber, wherein:
the second edge is opposite the first edge;
the second electrode is disposed adjacent to the chamber lid; and
the first electrode is disposed adjacent to the substrate support assembly.

16. The method of claim 15, wherein the first electrode and the second electrode are aligned parallel to a surface of the substrate support assembly.

17. The method of claim 15, wherein:
the first electrode is a bias electrode; and
the second electrode is a RF return electrode that is coupled to ground.

18. The method of claim 11, wherein a filter assembly is coupled between the second electrode and the DC supply.

19. The method of claim 11, wherein the voltage is between 0 volts and 300 volts.

20. The method of claim 18, wherein the voltage is between 150 volts and 250 volts.
